(19) United States
(12) Patent Application Publication
(10) Pub. No.: US 2026/0095024 A1
(43) Pub. Date: Apr. 2, 2026

(54) PLANAR OUTPUT COUPLER FOR VERTICAL EXTENDED CAVITY SURFACE EMITTING LASER ELEMENTS

(71) Applicant: Apple Inc., Cupertino, CA (US)

(72) Inventors: Omer Korech, Herzliya (IL); Chin Han Lin, Santa Clara, CA (US); Fei Tan, Sunnyvale, CA (US)

(21) Appl. No.: 19/330,623

(22) Filed: Sep. 16, 2025

Related U.S. Application Data
(60) Provisional application No. 63/700,294, filed on Sep. 27, 2024.

(51) Int. Cl. H01S 5/183; H01S 5/14

(52) U.S. Cl. CPC H01S 5/18377; H01S 5/141; H01S 5/18388

(57) ABSTRACT

A laser assembly includes a vertical cavity surface emitting laser and a resonant cavity extension. The resonant cavity extension is defined by two separate portions. A first portion may be formed from gallium arsenide and can define a microlens. A silicon dioxide layer can be disposed over the first portion and may be polished to a flat, planar surface. Reflective layers may interpose the first portion and second portion of the resonant cavity extension, and a reflective layer may be disposed over the planar surface. As a result of this construction, an extended cavity vertical surface emitting laser can be defined that is resistant to mode hopping and exhibits improved coherence length, beam divergence (high numerical aperture), and beam quality.

### CROSS-REFERENCE TO RELATED APPLICATION

This application claims the benefit under 35 U.S.C. § 119(e) of U.S. Provisional Patent Application No. 63/700,294 , filed Sep. 27, 2024, the contents of which are incorporated herein by reference as if fully disclosed herein.

### TECHNICAL FIELD

Embodiments described herein relate to light emitting elements and, in particular, to vertical extended cavity surface-emitting laser elements with a large oxide aperture that also exhibit a high numerical aperture, such that a product of the numerical aperture and the oxide aperture radius is larger than a beam parameter product.

### BACKGROUND

Vertical cavity surface-emitting lasers (VCSELs) have many advantages over diode laser elements and diode-pumped solid state laser elements, especially with respect to manufacturing. However, VCSEL elements are power-limited and exhibit significantly shorter coherence lengths, among other disadvantages and/or trade-offs, rendering VCSELs unsuitable for many applications (e.g., long range frequency-modulated continuous wave ranging applications).

Extending a resonant cavity of a VCSEL can increase coherence length and can improve beam quality at higher power with larger oxide apertures. These architectures can be referred to as vertical extended cavity surface-emitting lasers (VECSEL). Although providing many advantages over VCSELs, VECSELs with large oxide apertures may not exhibit desirable divergence, requiring separate microlens elements, increasing manufacturing cost and complexity.

### SUMMARY

Embodiments described herein can take the form of a laser assembly including at least a vertical cavity surface emitting laser (VCSEL) defined at least in part by an oxide aperture (e.g., 10 μm diameter or greater) and a resonant cavity extension coupled to and/or integrally formed with the VCSEL, so as to cooperatively define a VECSEL.

The laser assembly can include at least a first portion and a second portion. The first portion can include a substrate formed from a semiconductor material such as gallium arsenide (GaAs) and may define a microlens aligned with the VCSEL. The microlens can include an antireflective layer, although this is not required of all embodiments.

The second portion can include a substrate formed from silicon dioxide (SiO₂) and may define a first surface contouring to the first portion and a planar output surface opposite the first surface. The laser assembly can further include a partial reflector disposed on the planar output surface, thereby defining an extent of an extended resonant cavity defined between the first reflector and a second reflector within the VCSEL. As a result of this construction, the laser assembly can exhibit a higher numerical aperture than would otherwise be defined by the oxide aperture alone.

### BRIEF DESCRIPTION OF THE DRAWINGS

Reference will now be made to representative embodiments illustrated in the accompanying figures. It should be understood that the following descriptions are not intended to limit this disclosure to one included embodiment. To the contrary, the disclosure provided herein is intended to cover alternatives, modifications, and equivalents as may be included within the spirit and scope of the described embodiments, and as defined by the appended claims.

FIGS. 1A-1B depict an example electronic device that can incorporate one or more ranging systems that incorporate one or more VECSEL elements as described herein.

FIG. 2 depicts an example system diagram of an electronic device that can incorporate a ranging system that can incorporate one or more VECSEL elements as described herein.

FIG. 3A depicts another example laser assembly having a back-side emission laser and a back-side resonant cavity extension incorporating an on-chip lens and a planar output coupler/mode filter.

FIG. 3B depicts an example laser assembly having a front-side emission laser and a back-side resonant cavity extension incorporating an on-chip lens and a planar output coupler/mode filter.

FIG. 4 depicts an example laser assembly having a front-side emission laser and a back-side resonant cavity extension incorporating an on-chip lens and a planar output coupler including a multi-etalon mode filter.

FIG. 5 depicts an example laser assembly having a front-side emission laser and a back-side resonant cavity extension incorporating an on-chip lens and a planar output coupler disposed over an air gap.

FIG. 6 depicts an example laser assembly having a front-side emission laser, an integrated photodetector, and a back-side resonant cavity extension incorporating an on-chip lens and a planar output coupler disposed over an air gap.

The use of the same or similar reference numerals in different figures indicates similar, related, or identical items.

The use of cross-hatching or shading in the accompanying figures is generally provided to clarify the boundaries between adjacent elements and also to facilitate legibility of the figures. Accordingly, neither the presence nor the absence of cross-hatching or shading conveys or indicates any preference or requirement for particular materials, material properties, element proportions, element dimensions, commonalities of similarly illustrated elements, or any other characteristic, attribute, or property for any element illustrated in the accompanying figures.

Additionally, it should be understood that the proportions and dimensions (either relative or absolute) of the various features and elements (and collections and groupings thereof) and the boundaries, separations, and positional relationships presented therebetween, are provided in the accompanying figures merely to facilitate an understanding of the various embodiments described herein and, accordingly, may not necessarily be presented or illustrated to scale, and are not intended to indicate any preference or requirement for an illustrated embodiment to the exclusion of embodiments described with reference thereto.

### DETAILED DESCRIPTION

Embodiments described herein relate to laser assemblies and, in particular, wafer-level assemblies incorporating extended resonant cavities. Specifically, embodiments described herein relate to laser elements with large oxide apertures (e.g., 10 μm), while also exhibiting a high numerical aperture. Although many embodiments described herein relate to vertical cavity surface-emitting lasers with extended cavities (referred to as vertical extended-cavity surface-emitting lasers, or “VECSELs”), it may be appreciated that the techniques and architectures described herein can be suitably adapted for other types of lasers, such as edge emitting diode lasers.

Further, it may be appreciated that a resonant cavity extension can be positioned to extend a back-side or a front-side of a given laser assembly. In particular, a resonant cavity extension may be defined with reference to a substrate onto which a laser element is formed, mounted, attached, or otherwise disposed. In either a front-side or back-side extension construction, at least one reflective surface defining an extent of a resonant cavity is positioned apart from an epitaxial stack defining the laser itself. For simplicity of description, many embodiments described herein reference back-side emission laser cavities, but it may be appreciated that other constructions are possible.

More generally and broadly, embodiments described herein relate to cavity extensions for back-side emission lasers. In some cases, the cavity extension may be positioned opposite a beam output surface of the laser assembly, whereas in other cases, the cavity extension may be coupled to a beam output surface of the laser assembly. More simply, in some cases, a cavity extension as described herein may include a highly-reflective surface coating (e.g., a distributed Bragg reflector (“DBR”) stack) encouraging beam emission from an opposite side of the resonator cavity whereas in other constructions, a resonant cavity extension as described herein may include a DBR with lower reflectivity, thereby permitting partial emission therethrough.

A cavity extension can at least partially define an extent of a resonant cavity, or more simply a “length” of the resonant cavity that extends in two directions from an active layer of a VCSEL, which may vary from embodiment to embodiment and/or may vary by desired output wavelength of a laser assembly. In one embodiment, a cavity extension may extend a resonant cavity on the order of 100 micrometers (μm). In other cases, a cavity extension may extend a greater or shorter distance. In yet other cases, a cavity extension can include one or more air gaps. More simply, a laser cavity as described herein can include at least two reflective surfaces (e.g., DBRs) disposed between which is an active layer from which photons may be stimulated to emit coherently. The length separating the two reflective surfaces may define an extended resonant cavity that exceeds a length of a conventional VCSEL element.

A cavity extension or extended cavity as described herein can be formed in multiple portions (or layers), such as a first portion and a second portion. The first portion can be formed from a first material transparent to one or more wavelengths of electromagnetic radiation output by the laser assembly. Likewise, the second portion can be formed from a second material transparent to the same one or more wavelengths of light. The first material and the second material have, in many embodiments, differing indexes of refraction. In these constructions, more simply, laser light resonating with the resonant cavity can reflect back and forth within the cavity extension, passing through each of the first portion and the second portion.

The portions of a cavity extension or extended cavity as described herein perform different functions. A first portion can be configured with one or more refractive optical elements to concentrate resonating laser light within the cavity so as to increase coherence length and beam quality of a beam output from the laser assembly. A second portion of the cavity extension can be configured to operate as a planar output coupler and/or a mode filter. In view of the foregoing, the first portion of the cavity extension can also be referred to herein as a “lensing portion” and the second portion of the cavity extension can also be referred to herein as a “mode filtering portion” or a “planar output coupler portion.”

In many constructions, the lensing portion of a cavity extension may be defined at least in part from a gallium arsenide (GaAs) having a first surface opposite a second surface. The first surface may be a planar surface and maybe configured to optically and mechanically couple to a resonant cavity of a VCSEL element, thereby defining a VECSEL element. The second surface can have defined thereon an array of at least one microlens having a generally convex and/or near parabolic cross-sectional (typically, although not required, angularly-symmetric).

The array of microlenses can be formed over the second surface in a number of suitable ways.

For example, a GaAs substrate of a selected thickness can be masked with a suitable photoresist (e.g., an ultraviolet photoresist) to define one or more circular regions. Thereafter, an anisotropic etching process (e.g., a phosphoric acid wet etch operation) can be performed to define a series of circular columns of a particular height defined by the duration of the etch process. Thereafter the GaAs substrate, having defined thereon an array of circular columns, can be heated to encourage reflow of the columns into near parabolic lens shapes which may be defined in substantial part by a temperature-specific surface tension of liquid-phase GaAs. In other cases, the substrate can be formed from other materials and/or a lens can be formed in another manner. Thereafter the substrate may be cooled. In this example, the substrate with microlenses may be required to be physically aligned with an array of VCSELs; as noted above, this requirement does not often result in optimal manufacturing efficiency, speed, or part rejection rates.

To address issues and inefficiencies attendant to manufacturing techniques requiring precise physical alignment of separately-manufactured VCSEL arrays and microlens arrays, embodiments described herein form VCSEL elements and GaAs substrate layers in the same semiconductor manufacturing processes. More specifically, a GaAs substrate may be formed onto and/or disposed onto an epitaxial stack defining an array of VCSELs. Thereafter, microlenses can be formed using a suitable photolithographic process, such as described above. In these constructions, precise alignment of microlenses with respective VCSEL elements is dramatically simplified because it is not required to physically align two separate substrates.

In these embodiments, once microlenses are formed and/or otherwise defined over respective VCSEL elements, a partially reflective DBR can be formed over the microlenses and over portions of the second surface of the GaAs substrate between individual microlenses. In other cases, and/or in some embodiments, the microlenses and the surface from which they extend can be coated with an antireflective (“AR”) coating.

Over the partially reflective DBR (and/or AR coating) can be disposed and/or grown an optically transparent dielectric layer to define a second portion of the cavity extension. The dielectric layer can be formed from silicon dioxide (SiO₂) or another transparent material having a different index of refraction from the first portion (e.g., different from GaAs). Like the GaAs layer, this dielectric layer can define two surfaces. A first surface that contours to and follows a cross-sectional profile of the DBR-coated (and/or AR coated) microlens array and a second surface opposite the first surface. In embodiments described herein, the second surface is a flat, or planar surface. Over the second surface of the second portion of the cavity extension can be formed another DBR layer, which may be a highly reflective DBR layer or a partially reflective DBR layer.

In many embodiments, the second portion of the cavity extension can be formed to a thickness that resonates at a particular mode selected from possible modes of the first portion. As a result of this construction, only light with specific wavelength and mode profile which has high enough reflectivity from both portions can be built up as a resonance mode and reaching lasing operation from the complete device composed of both portions. This structure prevents mode hopping or in another phrasing encourages single mode operation. In some cases, additional etalons can be disposed over the second portion so as to increase mode filtering and/or single mode stability.

As a result of these described configurations, a VCSEL can be provided with an extended cavity to define a VECSEL. The extended cavity can include at least two portions, a first portion including a lens element and a second portion that includes a flat output coupler surface. As a result of this construction, an extended cavity is provided with a precisely-aligned microlens and a planar output surface. This architecture serves to increase coherence length, beam quality, output single mode power and possibly beam divergence while also dramatically improving manufacturing efficiency, speed, and reliability. Further still, it may be appreciated that the second portion serves as an encapsulation layer over the first portion, thereby protecting the microlenses from damage or alignment drift over time.

In many cases, a VECSEL as described above can be formed in an array such that multiple VECSEL elements are formed in a single process. A VECSEL array as described herein can be leveraged for a variety of suitable purposes including, as one example, ranging sensors and/or precision depth sensors for small form-factor electronic devices. More specifically, as a result of the increased coherence length resulting from the architectures described above, a VECSEL array as described herein can be operated as a frequency-modulated continuous wave ranging devices configured to inform an electronic device a distance to and/or a velocity of an object within a field of view of that electronic device.

For example, an electronic device such as a cellular phone may be configured with a proximity sensor to determine a distance to a user of the cellular phone. The proximity sensor may leverage a VECSEL or VECSEL array as described herein.

As another example, an electronic device may be a wearable electronic device such as a smart watch. In these examples, the smart watch may leverage one or more ranging or depth sensing operations to determine whether a user is wearing the watch or whether the watch is placed on a surface or charger. In other cases, a wearable electronic device such as a head-mounted display can leverage ranging systems and/or depth sensing systems to determine a location and/or pose or position of a wearer's hands or body, or track the wearer's gaze direction.

As yet another example, an imaging device such as a camera or camera element of a cellular phone may leverage a ranging system or depth sensing system to inform autofocus operations.

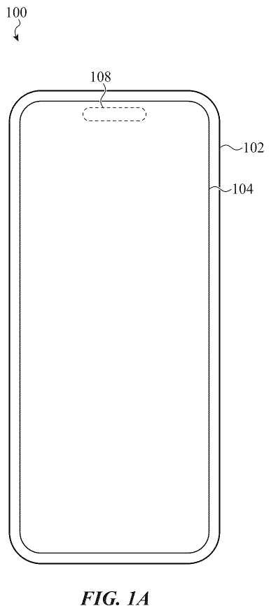

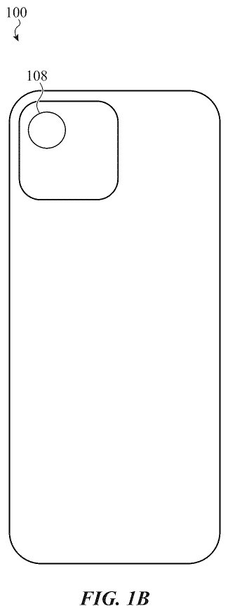

These foregoing and other embodiments are discussed below with reference to FIGS. 1A-6. However, those skilled in the art will readily appreciate that the detailed description given herein with respect to these figures is for explanation only and should not be construed as limiting.

In particular, FIGS. 1A-1B depict an example electronic device that can incorporate one or more ranging systems that incorporate one or more VECSEL elements or arrays as described herein.

FIG. 1A depicts an example electronic device 100. The electronic device 100 may be a portable electronic device, such as a cellular phone, wearable device, or tablet computing device. It may be appreciated, however, that a portable electronic device is merely one example device that can include a ranging and/or depth-sensing system as described herein. It may be appreciated that VECSEL array as described herein can be incorporated into a number of different applications, sensors, input components, or otherwise; for simplicity of description and illustration, the embodiments that follow reference an example application in which a first VECSEL array as described herein is leveraged by a depth sensing system of an electronic device and a second VECSEL array is leveraged by a ranging system of the same electronic device. It is appreciated, however, that these are merely examples. An electronic device, such as the electronic device 100 can include one or more components that leverage a VECSEL as described herein, which may be similarly or differently configured.

The electronic device 100 as depicted in FIG. 1A is defined at least in part by a low-profile housing, identified as the housing 102. The housing 102 can enclose and support one or more components of the electronic device 100, such as a processor, one or more memory components or circuits, a battery, and a display 104. For simplicity of description and illustration, FIG. 1A is depicted without many of these components; a person of skill in the art may readily appreciate that a number of components, circuits, structures, and systems can be included in the housing 102 of the electronic device 100. For example, the electronic device 100 can include a processor configured to access a memory to instantiate a software application configured to render a graphical user interface via the display 104.

The software application can, in some examples, be configured to integrate with one or more hardware sensors or sensing systems of the electronic device 100, such as a ranging and/or depth-sensing system. In some embodiments, a ranging system 106 can be positioned below the display 104 and/or may be integrated at least partially with the display 104. The ranging system 108 can include an array of VECSELs coupled to a controller, processor, or drive circuitry.

The controller can provide, as output, a time-varying current signal configured to drive one or more of the VECSELs of the array to produce, as one example, frequency-modulated continuous wave (“FMCW”) output for radial velocity tracking and/or distance measurement to one or more objects nearby the electronic device 100. For example, FMCW ranging techniques can be used by the controller of the ranging system 108 to detect a position of a user of the electronic device 100 relative to the housing 102. More specifically, the ranging system 108 can be used as a proximity sensor, as a portion of a structured light depth mapping system, an autofocus assistant for a front-facing camera, or for any other suitable depth finding or ranging purpose.

In some cases, an electronic device such as the electronic device 100 can include multiple sensors or systems that leverage an array of VECSELs as described herein. For example, FIG. 1B depicts the example electronic device of FIG. 1A, showing a second, rear-facing system, labeled as the depth sensing system 118. The depth sensing system 118 may be associated with and/or may be disposed alongside (or within) a camera system, or a barrel or lens group thereof, of the electronic device 100. In these examples, the depth sensing system 118 can be used to assist autofocus, to select one or more zoom parameters, to determine objects and locations thereof in a scene and so on.

These foregoing embodiments depicted in FIGS. 1A-1B and the various alternatives thereof and variations thereto are presented, generally, for purposes of explanation, and to facilitate an understanding of various configurations and constructions of a portable electronic device that can incorporate a ranging and/or depth-sensing system that includes a variable aperture, such as described herein. However, it will be apparent to one skilled in the art that some of the specific details presented herein may not be required in order to practice a particular described embodiment, or an equivalent thereof.

Thus, it is understood that the foregoing and following descriptions of specific embodiments are presented for the limited purposes of illustration and description. These descriptions are not targeted to be exhaustive or to limit the disclosure to the precise forms recited herein. To the contrary, it will be apparent to one of ordinary skill in the art that many modifications and variations are possible in view of the above teachings.

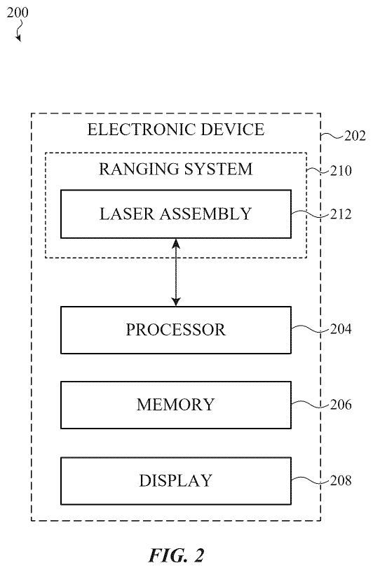

FIG. 2 depicts an example system diagram of an electronic device that can incorporate a ranging system that can incorporate one or more VECSEL elements as described herein. The system diagram 200 includes an electronic device 202 can include a processor 204, a memory 206, and (optionally) a display 208. As noted with respect to other embodiments described herein, the processor 204 can be configured to access the memory 206 to retrieve one or more computer-executable instructions and/or other executable assets in order to instantiate one or more instances of software that, in turn, may perform or coordinate one or more operations of the electronic device 202.

As an example, the processor 204 and the memory 206 can cooperate with the display 208 to render a graphical user interface via the display 208. The graphical user interface and/or the display may change between modes based on proximity to a user of the electronic device, which may be detected by a ranging system 210. For example, it the ranging system 210 determines that a user of the electronic device 202 is closer than a threshold distance, the display 208 may be dimmed, disabled, or may be otherwise changed. For example, if the electronic device 202 is a cellular phone, the ranging system 210 can be used to determine whether the electronic device 202 is being held within a threshold distance of the user's ear, head or other body part during a telephone call. To prevent unintentional engagement with a touch sensor associated with the display 208, the electronic device 202 may disable the display 208 entirely if the ranging system 210 determines that the electronic device 202 is within a threshold distance (e.g., 5 centimeters, in some embodiments) of the user's ear. The display may be re-enabled by the processor 204 in response to input from the ranging system 210 indicating that the user has withdrawn the electronic device 202.

The ranging system 210 can include a laser assembly 212. The laser assembly 212 can include a VECSEL array, as described herein, and at least one controller or driving circuit configured to drive the VECSELs of the VECSEL array to perform FMCW ranging operations.

As noted above, each VECSEL of the array can include a VCSEL element and an extended resonant cavity. The extended resonant cavity can include and/or may be defined by at least two discrete portions, a first portion includes an on-chip lens (“OCL”) aligned with a beam axis of the VCSEL element (e.g., generally along a centerline of the extended resonant cavity) and a second portion that engages with and/or contours to the first portion, encapsulating the first portion and defining a planar, flat, surface opposite therefrom. The resonant cavity can be terminated with one or more DBRs, which may be highly or partially reflective, depending on configuration. In some cases, the cavity can further include one or more additional etalons (e.g., dielectric layers of a material such as SiO2 disposed with DBRs on opposite surfaces thereof) to serve as mode filters. As a result of these described constructions, the resonant cavity of the VCSEL is extended and, due to the OCL, light resonating within the extended cavity is confined along the beam axis and better resonates, thereby increasing coherence length to a suitable distance that supports FMCW operation of the ranging system 210.

Although FIGS. 1A-2 describe an example application of VECSELs as described herein, it may be appreciated that incorporation into an electronic device for ranging purposes is merely one example. In other cases, a VECSEL can be used for any other suitable purpose for which a laser element may be suitable. As such, it may be appreciated that the foregoing example applications are non-limiting of the applications in which a VECSEL as described herein, and the architecture thereof, may be used.

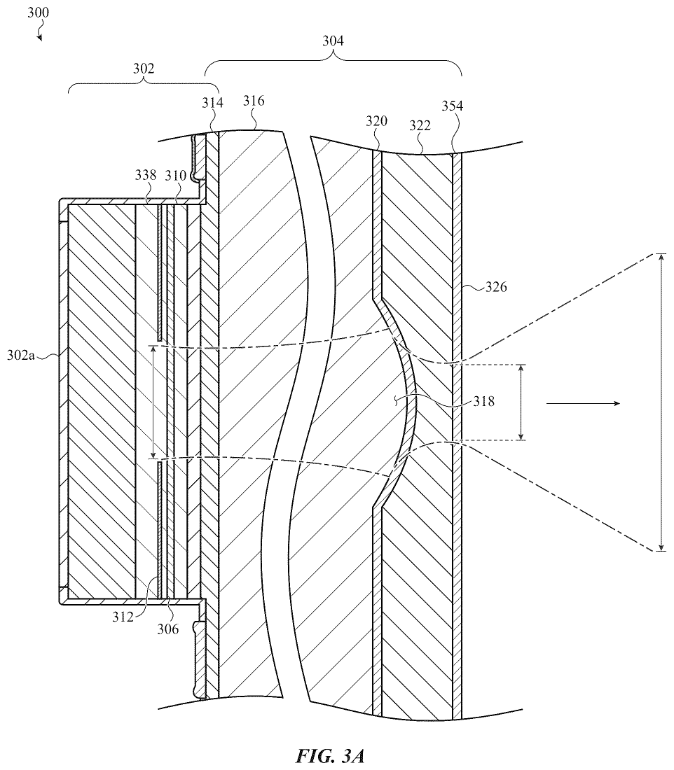

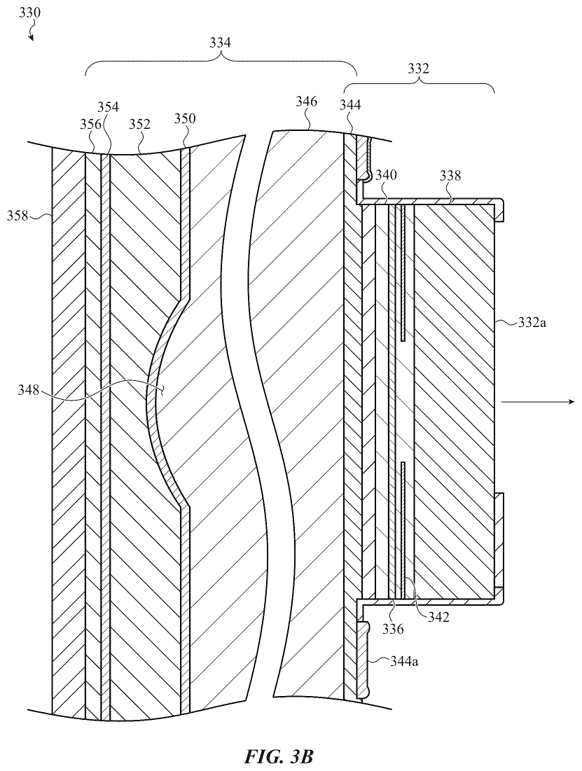

Generally and broadly FIGS. 3A-6 depict cross-sections of example VECSELs including extended resonant cavities with multiple portions as described herein. These figures and example embodiments are presented to emphasize that a multi-portion extended resonant cavity as described herein can be leveraged in a number of suitable ways, by both front-side emission VCSELs and back-side emission VCSELs. As used herein, directional terminology, such as “top,” “bottom,” “upper,” “lower,” “front,” “back,” “left,” “right,” and the like is used with reference to the orientation of some of the components in some of FIGS. 3A-5. Because components in various embodiments can be positioned in a number of different orientations, direction terminology is used for purposes of illustration only and is not specifically limiting. The directional terminology is intended to be construed broadly, and should not be interpreted to preclude the orientation of components in different ways. For simplicity of illustration, the figures are presented herein as emitting light from left to right, but it may be appreciated that this is non-limiting.

FIG. 3A depicts the laser assembly 300 is configured for back-side emission. Specifically, an epitaxial stack defines a laser 302 that is configured to emit light in a direction through a surface onto which the laser 302 is formed. As with other embodiments described herein, the laser 302 is coupled to a multiportion resonant cavity extension 304. In this configuration, the multiportion resonant cavity extension 304 is opposite to a capped front surface 302a of the laser 302. The capped front surface 302a can be formed from a reflective material or a metal material, such as gold.

As with other embodiments described herein, in the illustrated embodiment, the laser 302 is defined at least in part by an epitaxial stack of layer that cooperatively operate to stimulate emission of photons of particular wavelengths, such as in the infrared band or the visible band.

The laser 302 includes an active layer 306 separating a first reflector 308 and a second reflector 310, which may be optional in some embodiments. The first reflector 308 may be a p-doped DBR while the second reflector 310 may be an n-doped DBR. In other cases, other reflector types or arrangements may be suitable. The first reflector 308 and the second reflector 310 may each be formed as distributed Bragg reflectors configured to preferentially reflect wavelengths of photons emitted form the active layer 306.

The laser 302 can also include an oxide aperture 312 or other mask layer that effectively shapes the beam output from the laser 302 via the beam output surface.

As with other embodiments described herein, the laser 302 can be formed onto, adhered to, and/or coupled to a substrate such as the control substrate 314. The control substrate 314 can include and/or can be coupled to one or more circuits or systems configured to apply current to the laser 302 to stimulate laser light emission.

The first reflector 308 and the second reflector 310 may be partially reflective. In a more general phrasing, each of the first reflector 308 and the second reflector 310 can be specifically configured to allow a portion of light incident thereto to pass through. In some cases, the second reflector 310 can have different reflectiveness for different frequencies, polarizations, or directions of incident light. For example, light passing through one direction may be reflected with a first reflectivity whereas light passing through in an opposite direction may experience a second reflectivity. Independent of reflectivity selected and/or designed for a particular application of the laser 302, at least a portion of light may be emitted through the control substrate 314 into the multiportion resonant cavity extension 304, which can be formed onto and/or with the laser 302 and/or the control substrate 314. The multiportion resonant cavity extension 304 may be bonded to the control substrate 314 via an adhesive, oxide bond, or other inter-layer or inter-substrate bond.

The multiportion resonant cavity extension 304 includes a first portion 316. The first portion 316 can be formed to a suitable thickness of a material such as GaAs or other semiconductor material substrate where the VeCSEL epitaxy is grown on; the thickness may vary from embodiment to embodiment. As with other embodiments described herein, the first portion 316 includes an optical element 318 that can define a lens over the laser 302. The optical element 318 can be formed from a second surface of the first portion 316 that is opposite a first surface of the first portion 316 that is bonded or adhered to the control substrate 314 and/or the laser 302.

In many cases, the optical element 318 may be a near-parabolic microlens formed by reflowing a circular column anisotropically etched into the first portion 316, as one example. In other cases, the optical element 318 can be formed with a different process. A third optical layer 320 can be formed over the second surface of the first portion 316. The third optical layer 320 can be any suitable optical layer. In some cases, the third optical layer 320 can include an antireflective coating. In certain embodiments, the third optical layer 320 can be at least partially reflective, although this is not required.

The multiportion resonant cavity extension 304 further includes a second portion 322 coupled and contoured to the second surface of the first portion 316. Specifically the second portion 322 can be disposed over the third optical layer 320 and/or bonded to the third optical layer 320. Specifically, the second portion 322 can include a first surface and a second surface, separated by a body. The first surface of the second portion 322 can be coupled to the third optical layer 320, and may be a nonplanar surface, as the first surface is configured to engage with and contour to a profile of the optical element 318 and other planar or non-lensing portions of the first portion 316.

The second portion 322 includes a second surface opposite the first surface. The second surface in many embodiments can be finished, polished and/or disposed to be a planar surface. In this manner, a thickness of the second portion 322 over the optical element 318 may be less than a thickness of the second portion 322 over other portions of the third optical layer 320. In many examples, the second portion 322 is formed from a dielectric and/or passivating material such as silicon dioxide but this may not be required of all embodiments. In some cases, silicon nitride, crystalline silicon or other materials may be suitable.

As with other embodiments, a fourth reflector 324 can be disposed over the second surface of the second portion 322. The fourth reflector 324 can be a partially reflectivity coating defining an end extent of the multiportion resonant cavity extension 304. To support and/or encapsulate the fourth reflector 324, an optional output coupling substrate can be disposed over the fourth reflector 324. and may define a beam output surface 326.

As a result of the depicted construction, light stimulated from the active layer 306 can reflect from the first reflector 308, through the active layer 306 to become incident upon the second reflector 310. A portion of this light enter the multiportion resonant cavity extension 304 through by the second reflector 310 (optional, in some cases it may be omitted or may not be reflective) and the contact layer 344. In the illustrated construction, light entering the multiportion resonant cavity extension 304 first enters the first portion 316, and may be reflected by the parabolic shape of the optical element 318 toward the control substrate 314, the second reflector 310, and the active layer 306. As may be appreciated, the parabolic shape serves to focus light within the multiportion resonant cavity extension 304 toward a central/medial axis of the laser 302.

As described in respect of other embodiments described herein, at least a portion of light incident upon the optical element 318 may be transmitted through the optical element 318 to traverse the second portion 322 of the multiportion resonant cavity extension 304. Thereafter, this light may be reflected by the highly reflective layer, the fourth reflector 324, to traverse through the multiportion resonant cavity extension 304 in the opposite direction.

In this manner, photons stimulated from the active layer 306 resonate between the first reflector 308 and the fourth reflector 324, being concentrated and/or refracted by the optical element 318. As light passes through the optical element 318, it can exit the laser assembly 300 via the surface of the fourth reflector 324. It may be appreciated that as a result of the flat surface of the reflector 324, a beam waist of the output beam may be reduced, thereby exhibiting higher beam divergence.

More particularly, a conventional VECSEL without a planar output coupler and lens as described herein and as depicted in the drawings exhibits only a single beam waist, which is at least in part defined by, and may have similar dimension as the oxide aperture thereof. It may be appreciated that as oxide apertures (and/or other aperture-defining layers within a VCSEL or VECSEL's resonant cavity) also functionally limit effective (accessible) gain cross section and hence output power. In other words, greater output power may be achieved with a larger oxide aperture, at the expense of lower numerical aperture (beam divergence). More specifically, larger oxide apertures exhibit strong collimation effects, resulting in a small numerical aperture which may not be suitable for all applications in which laser light at higher power is required, because high collimation at the laser source is manifested in narrow beam diameter at the collimating lens (whose distance from the laser is much longer than the cavity length), thus the collimation by the external lens is lower bounded due to the diffraction limit of collimation, which is inversely proportional to the beam size at the lens.

To circumvent this limitation, many embodiments described herein including the laser assembly 300 and in particular the optical element 318, can serve to increase numerical aperture by effectively introducing a second beam waist that is smaller than the first beam waist. The second beam waist results in a greater beam divergence.

The optical element 318 can be design and/or shaped to induce a particular beam divergence and/or to effectuate a particular numerical aperture. More broadly, it may be appreciated that the cross-sectional/profile shape of the optical element 318 can vary from embodiment to embodiment and may be specifically selected and shaped to introduce a particular beam waist.

For embodiments described herein, the second beam waist may intersect at the fourth reflector 324. More specifically, since a central axis of the optical element 318 can be lithographically aligned with the center of oxide aperture 312, the second beam waist may automatically align with the first beam waist defined by oxide aperture 312. In this manner, manufacturing tolerances for the laser assembly 300 are relaxed, as the laser assembly 300 by its very operation, locks to not only a particular mode, but also with the second beam waist aligned with the first beam waist defined by the oxide aperture 312.

These foregoing embodiments depicted in FIG. 3A and the various alternatives thereof and variations thereto are presented, generally, for purposes of explanation, and to facilitate an understanding of various configurations and constructions of a laser assembly and extended resonant cavity, such as described herein. However, it will be apparent to one skilled in the art that some of the specific details presented herein may not be required in order to practice a particular described embodiment, or an equivalent thereof.

Thus, it is understood that the foregoing and following descriptions of specific embodiments are presented for the limited purposes of illustration and description. These descriptions are not targeted to be exhaustive or to limit the disclosure to the precise forms recited herein. To the contrary, it will be apparent to one of ordinary skill in the art that many modifications and variations are possible in view of the above teachings.

For example, in other embodiments, an optical element within a resonant cavity can serve other purposes such as for one or more improved beam characteristics such as mode locking.

FIG. 3B depicts an example laser assembly having a front-side emission laser and a back-side resonant cavity extension incorporating an on-chip lens and a planar output coupler/mode filter.

As with other embodiments described herein, the laser assembly 330 includes a VCSEL coupled to an extended cavity. The extended resonant cavity can be formed integrally with the VCSEL in a series of common semiconductor manufacturing operations. In this manner, precise and accurate alignment of features of the extended cavity and features of the VCSEL can be ensured. As noted above, a VCSEL can be configured for front-side emission or back-side emission. As known to a person of skill in the art, orientation of reflectors defining a resonant cavity of the VCSEL (whether internal or externally extended) define an emission surface of a VCSEL.

In FIG. 3B, the laser assembly 330 is configured for front-side emission. Specifically, an epitaxial stack defines a first laser assembly portion 332 that is configured, when cooperating with the resonant cavity extension 334, to emit light normal to a surface onto which the first laser assembly portion 332 is formed. This is merely one example construction; in other examples, a laser assembly such as the laser assembly 330 can be oriented for back-side emission.

A back side of the first laser assembly portion 332 is coupled to a multiportion resonant cavity extension 334. In this configuration, the multiportion resonant cavity extension 334 is opposite a beam output surface 332a of the first laser assembly portion 332.

In the illustrated embodiment, the first laser assembly portion 332 is defined at least in part by an epitaxial stack of layer that cooperatively operate to stimulate emission of photons of particular wavelengths. Specifically, the first laser assembly portion 332 includes an active layer 336 separating a first reflector 338 and a second reflector 340. The active layer 336 includes and/or is formed with a material with a selected band cap to encourage emission of photons. The first reflector 338 may in some embodiments be a p-doped DBR while the second reflector 340 is an n-doped DBR. In other cases, the first reflector 338 may be an n-doped reflector and the second reflector 340 may be a p-doped reflector. Many constructions are possible.

The first reflector 338 and the second reflector 340 may each be formed as distributed Bragg reflectors configured to preferentially reflect wavelengths of photons emitted from the active layer 336. In this construction, photons stimulated from the active layer 336 that are aligned generally with a medial/central axis of the first laser assembly portion 332 reflect in a resonant manner between the first reflector 338 and the second reflector 340 (which may be optional in many embodiments; for embodiments including the second reflector 340, the second reflector 340 may provide partial reflection for cavity length and optical loss adjustments), passing through the active layer 336 multiple times and potentially stimulating emission of yet additional photons. In this manner, stimulated emission of light is achieved.

The first laser assembly portion 332 can also include an oxide aperture 342 or other mask layer that effectively shapes a beam output from the first laser assembly portion 332 via the beam output surface 332a. In this construction the first laser assembly portion 332 can be formed onto and/or coupled to a substrate such as the contact layer 344. The contact layer 344 can include and/or can be coupled to one or more circuits or systems configured to apply current to the first laser assembly portion 332 to stimulate laser light emission. The contact layer 344 can include one or more circuits, traces, or electrodes, such as the electrode 344a. In some embodiments the electrode 344a can be configured to conductively couple to one or more additional circuits or systems, such as an external laser diode driver circuit.

The first reflector 338 and the second reflector 340 may be partially reflective. In a more general phrasing, each of the first reflector 338 and the second reflector 340 can be specifically configured to allow a portion of light incident thereto to pass through. Reflectivity and/or transmissivity of the first reflector 338 or the second reflector 340 may vary from embodiment to embodiment. In another phrasing, the construction and/or materials selected to define the first reflector 338 and the second reflector 340 may vary from embodiment to embodiment. In

[symbol]

Independent of reflectivity selected and/or designed for a particular application of the first laser assembly portion 332, at least a portion of light may be emitted through the contact layer 344 into the multiportion resonant cavity extension 334. The multiportion resonant cavity extension 334 can be formed onto and/or with the first laser assembly portion 332 and/or the contact layer 344. The multiportion resonant cavity extension 334 may, in some cases, be bonded to the contact layer 344 via an adhesive, oxide bond, or other inter-layer or inter-substrate bond.

The multiportion resonant cavity extension 334 includes a first portion 346. The first portion 346 can be formed to a suitable thickness that may vary from embodiment to embodiment. In some cases, the first portion 346 can be formed from bulk GaAs to a thickness of 100 μm. In other cases, the first portion 346 can be formed to a different thickness. The first portion 346 includes an optical element 348 that can define a lens over the first laser assembly portion 332. The optical element 348 can be formed from a second surface of the first portion 346 that is opposite a first surface of the first portion 346 that is bonded or adhered to the contact layer 344 (and/or the first laser assembly portion 332).

In many cases, the optical element 348 may be a near-parabolic microlens formed by reflowing a circular column anisotropically etched into the first portion 346. More particularly, as noted above, the optical element 348 can be formed on the first portion 346 by first defining a circular pattern with a suitable resist material, such as a UV photoresist. Thereafter, an anisotropic etch process can be performed to define a circular column on the first portion 346. Once formed, the first portion 346 and/or the first laser assembly portion 332 coupled to the first portion 346 can be locally or globally heated to encourage reflow of the column. Surface tension of the column can thereafter adopt a lens shape when cooled. In other cases, heating and/or reflow may not be suitable. In these examples, lenses and/or other optical elements can be formed in another manner.

A third reflector 350 can be formed over the second surface of the first portion 346. The third reflector 350 can be a DBR, a silvering layer, another partially reflective layer. The natural Fresnel reflection at the interface may also form the reflector. In some cases, the third reflector 350 can include an antireflective coating to serve as lens (with minimal reflection). The multiportion resonant cavity extension 334 further includes a second portion 352 coupled and contoured to the second surface of the first portion 346. Specifically the second portion 352 can be disposed over the third reflector 350 and/or bonded to the third reflector 350. Specifically, the second portion 352 can include a first surface and a second surface, separated by a body. The first surface of the second portion 352 can be coupled to the third reflector 350, and may be a nonplanar surface, as the first surface is configured to engage with and contour to a profile of the optical element 348 and other planar or non-lensing portions of the first portion 346.

The second portion 352 includes a second surface opposite the first surface. The second surface in many embodiments can be finished, polished and/or disposed to be a planar surface. In this manner, a thickness of the second portion 352 over the optical element 348 may be less than a thickness of the second portion 352 over other portions of the third reflector 350. In many examples, the second portion 352 is formed from a dielectric and/or passivating material such as silicon dioxide but this may not be required of all embodiments. In some cases, silicon nitride, crystalline silicon or other materials may be suitable. In many cases, the second portion 352 is formed from a material having a different index of refraction from the first portion 346, but this is not required of all embodiments. In many embodiments, the second portion 352 has a material exhibiting a coefficient of thermal expansion that is similar to the first portion 346.

A fourth reflector 354 can be disposed over the second surface of the second portion 352. The fourth reflector 354 can be a high reflectivity coating defining an end extent of the multiportion resonant cavity extension 334. To support and/or encapsulate the fourth reflector 354, a backing substrate 356—which may be formed from silicon dioxide or another passivation material—can be disposed over the fourth reflector 354. Backing the backing substrate 356 may be a metal backing and/or heat sink layer, the heat sink layer 358. The heat sink layer 358 may be made from a thermally conductive metal, such as gold.

As a result of the depicted construction, light stimulated from the active layer 336 can reflect from the first reflector 338, through the active layer 336 to become incident upon the second reflector 340. A portion of this light may be reflected back to the first reflector 338 (through the active layer 336) and a portion of this light may traverse the second reflector 340 and the contact layer 344 to enter the multiportion resonant cavity extension 334. In the illustrated construction, light entering the multiportion resonant cavity extension 334 first enters the first portion 346, and may be reflected by the parabolic shape of the optical element 348 toward the contact layer 344, the second reflector 340, and the active layer 336. As may be appreciated, the parabolic shape serves to focus light within the multiportion resonant cavity extension 334 toward a central/medial axis of the first laser assembly portion 332.

At least a portion of light incident upon the optical element 348 may be transmitted through the optical element 348 to traverse the second portion 352 of the multiportion resonant cavity extension 334. This light may be collimated and/or refracted by the optical element 348 as that light traverses the bulk of the second portion 352. Thereafter, this light may be reflected by the highly reflective layer, the fourth reflector 354, to traverse through the multiportion resonant cavity extension 334 in the opposite direction. In this manner, photons stimulated from the active layer 336 resonate between the first reflector 338 and the fourth reflector 354, while passing through and being refracted and/or reflected by the third reflector 350 disposed over the optical element 348. As light passes through the active layer 336 and stimulates additional emission, a portion of light incident upon the first reflector 338, may pass through the first reflector 338 to exit the first laser assembly portion 332 from the beam output surface 332a as an output beam, shaped at least in part by the oxide aperture 342.

It may be appreciated that the foregoing example architecture can be modified in a number of suitable ways to perform a similar function. For example, the optical element 348 in some embodiments can include one or more: gratings; beam shapers; tilters; splitters; filters; and so on. In other cases, the optical element 348 may be intentionally offset from a medial axis of the first laser assembly portion 332 to preferentially emit light from the beam output surface 332a at an angle relative to a plane intersecting the beam output surface 332a.

It may be appreciated that the second portion 352 serves multiple purposes. For example, the second portion 352 encapsulates and protects the third reflector 350 and the optical element 348. Additionally, the second portion 352 defines a flat surface, a planar surface, that can serve as a host substrate for additional layers, etalons, structural features, electrical features, or optical output facets. Further, the second portion 352 and the backing substrate 356 can cooperatively operate together with the fourth reflector 354 and the third reflector 350 to define a mode filter that induces the first portion 346 to prefer single mode operation over multimode operation.

These foregoing embodiments depicted in FIGS. 3A-3B and the various alternatives thereof and variations thereto are presented, generally, for purposes of explanation, and to facilitate an understanding of various configurations and constructions of a laser assembly and extended resonant cavity, such as described herein. However, it will be apparent to one skilled in the art that some of the specific details presented herein may not be required in order to practice a particular described embodiment, or an equivalent thereof.

Thus, it is understood that the foregoing and following descriptions of specific embodiments are presented for the limited purposes of illustration and description. These descriptions are not targeted to be exhaustive or to limit the disclosure to the precise forms recited herein. To the contrary, it will be apparent to one of ordinary skill in the art that many modifications and variations are possible in view of the above teachings.

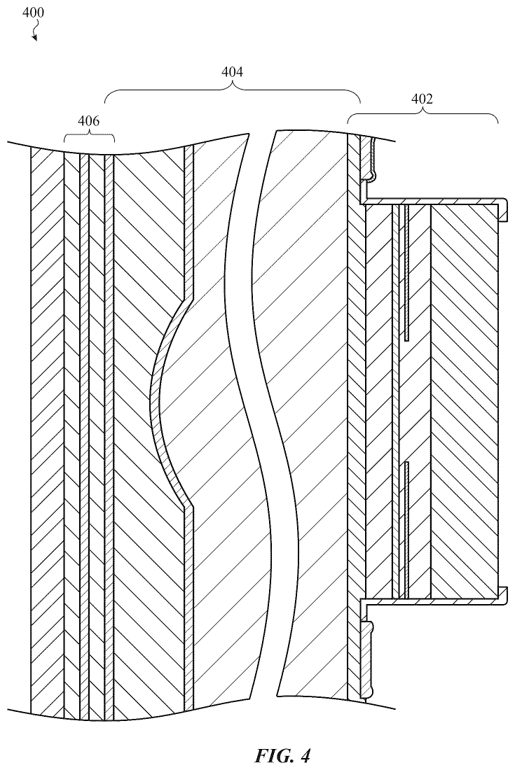

For example, in some embodiments, an extended resonant cavity as described herein can include multiple etalons layered below or relative to a flat output surface of the resonant cavity. As noted above, additional etalons (which may also be referred to as mode filters) can serve to encourage single-mode resonance within a first portion of the extended cavity. FIG. 4 depicts an example laser assembly having a front-side emission laser and a back-side resonant cavity extension incorporating an on-chip lens and a planar output coupler including a multi-etalon mode filter. In this example, the laser assembly 400 includes a VCSEL laser element 402 configured for front-side emission can be coupled to and/or integrally formed with a cavity extension 404. The cavity extension 404 can include a first portion with an optical element and a second portion coupled to the first portion the second portion defining a flat output coupler or reflector surface. In this example, the laser assembly 400 includes a set of etalons 406 formed onto and/or coupled to the second portion of the cavity extension 404. The set of etalons 406 which can include one or more additional etalons, can serve as a mode filter for the laser assembly 400. It may be appreciated that any suitable number of etalons can be added/appended to the cavity extension 404.

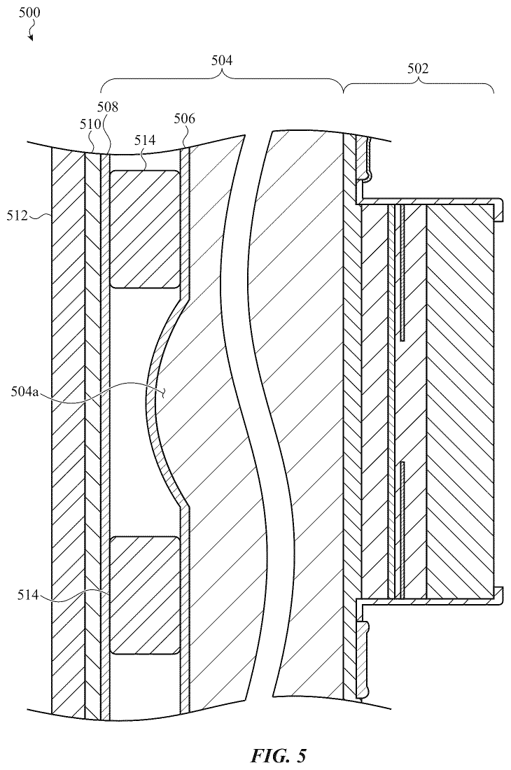

In other embodiments, a cavity extension as described herein can include one or more air gaps in addition to and/or in place of one or more substrate layers. FIG. 5 depicts an example laser assembly having a front-side emission laser and a back-side resonant cavity extension incorporating an on-chip lens and a planar output coupler disposed over an air gap. The laser assembly 500 includes a laser 502 coupled to a cavity extension 504. The cavity extension 504 includes a first portion defined by a substrate that has formed thereon a lens element 504a. The lens element 504a can extend into an air gap separating a first reflector 506 from a second reflector 508. The first reflector 506 can be disposed on the first portion of the cavity extension 504 and the second reflector 508 can be disposed on a backing substrate 510 that supports and/or bonds to a metal heatsink layer 512. An extent of the air gap is defined by spacers 514, which may be formed from a thermally and/or electrically conductive material such as gold.

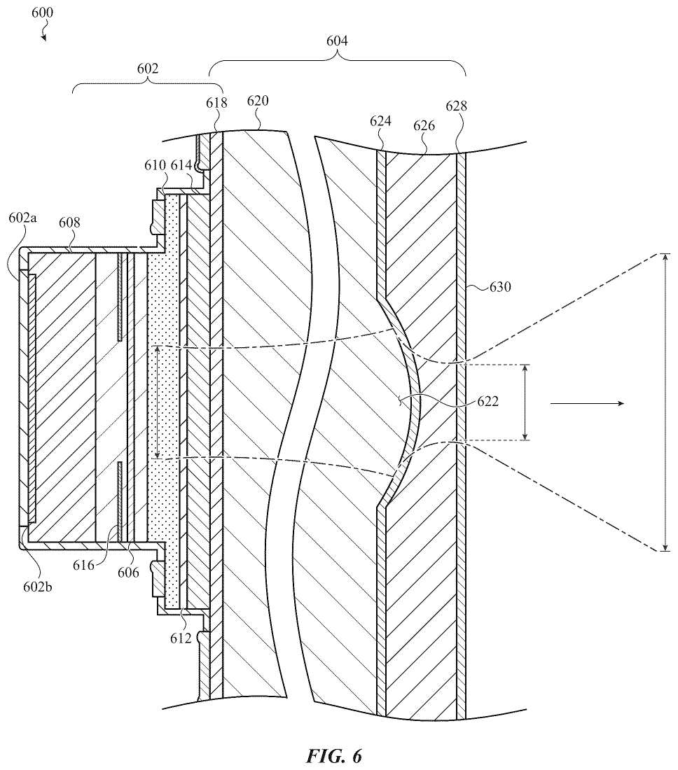

FIG. 6 depicts an example laser assembly having a front-side emission laser, a photodetector layer, and a back-side resonant cavity extension incorporating an on-chip lens, optionally one or more metasurface optical elements, and a planar output coupler/mode filter as with other embodiments described herein.

More specifically, FIG. 6 depicts the laser assembly 600 is configured for back-side emission. Specifically, an epitaxial stack defines a laser 602 that is configured to emit light in a direction through a surface onto which the laser 602 is formed.

As with other embodiments described herein, the laser 602 is coupled to a multiportion resonant cavity extension 604. In this configuration, as with other embodiments such as described above with respect to FIG. 3A, the multiportion resonant cavity extension 604 is opposite to a capped front surface 602a of the laser 602. The capped front surface 602a can be formed from a reflective material or a metal material, such as gold. Other materials may be suitable in other embodiments. In some cases, a metasurface optical element layer 602b can be disposed on the capped front surface 602a to affect one or more optical properties of light within the laser 602, such as polarization, phase, or the like.

In the illustrated embodiment, the laser 602 is defined at least in part by an epitaxial stack of layer that cooperatively operate to stimulate emission of photons of particular wavelengths, such as in the infrared band or the visible band.

The laser 602 includes an active layer 606 separating a first reflector 608 and a second reflector 610, which may be optional in some embodiments. The first reflector 608 may be a p-doped DBR while the second reflector 610 may be an n-doped DBR. In other cases, other reflector types or arrangements may be suitable. The first reflector 608 and the second reflector 610 may each be formed as distributed Bragg reflectors configured to preferentially reflect wavelengths of photons emitted form the active layer 606.

In the illustrated embodiment, the second reflector 610 may be positioned with respect to a photodetector absorption layer 612. The photodetector absorption layer 612 can be formed form a material that absorbs photons emitted from the active layer 606 and generates a measurable electrical signal in response. In this manner, the photodetector absorption layer 612 can serve as a photon-responsive element, photodiode, or the like. One or more electrodes may be conductively coupled to the photodetector absorption layer 612 to facilitate conductive coupling to an external measurement and/or circuit. In these constructions, the laser 602 may be driven with a chirp pulse or triangular pulse such that a frequency difference between a detected corresponding rise and fall can be correlated to a distance separating the laser 602 and an object form which light reflected.

As a result of this integrated photodetector, the laser 602 can be operated in self-mixing interferometric modes. More specifically, the photodetector absorption layer 612 can be used to probe changes in output wavelength that may results from destructive or constructive self mixing interference that may be induced by an object in free space that reflects light emitted from the laser 602. In this manner, the laser 602 can be operated as a high power, high numerical aperture, self-mixing interferometric device with a flat output coupler suitable for simplified optical coupling to a number of optical elements or media.

In some embodiments, the laser can also include another reflective layer bonded to and/or formed with the photodetector absorption layer 612. In this example, a reflective layer 614 can be partially transmissive so as to permit light output. In many cases, the reflective layer 614 can be formed from the same materials and/or layers as other reflectors of the laser 602; in other embodiments, a different construction may be suitable.

The laser 602 can also include an oxide aperture 616 or other mask layer that effectively shapes the beam output from the laser 602.

As with other embodiments described herein, the laser 602 including the photodetector absorption layer 612, can be formed onto, adhered to, and/or coupled to a substrate such as the control substrate 618. The control substrate 618 can include and/or can be coupled to one or more circuits or systems configured to apply current to the laser 602 to stimulate laser light emission.

The first reflector 608 and the second reflector 610 and the third reflector 614 may be partially reflective. In a more general phrasing, each of the first reflector 608 and the second reflector 610 and the third reflector 614 can be specifically configured to allow a portion of light incident thereto to pass through. In some cases, the second reflector 610 can have different reflectiveness for different frequencies, polarizations, or directions of incident light. For example, light passing through one direction may be reflected with a first reflectivity whereas light passing through in an opposite direction may experience a second reflectivity. Independent of reflectivity selected and/or designed for a particular application of the laser 602, at least a portion of light may be emitted through the control substrate 618 into the multiportion resonant cavity extension 604, which can be formed onto and/or with the laser 602 and/or the control substrate 618. The multiportion resonant cavity extension 604 may be bonded to the control substrate 618 via an adhesive, oxide bond, or other inter-layer or inter-substrate bond.

The multiportion resonant cavity extension 604 includes a first portion 620. As with other embodiments, the first portion 620 can be formed to a suitable thickness of a material such as GaAs or other semiconductor material substrate where the VeCSEL epitaxy is grown on; the thickness may vary from embodiment to embodiment. As with other embodiments described herein, the first portion 620 includes an optical element 622 that can define a lens over the laser 602. The optical element 622 can be formed from a second surface of the first portion 620 that is opposite a first surface of the first portion 620 that is bonded or adhered to the control substrate 618 and/or the laser 602.

In many cases, the optical element 622 may be a near-parabolic microlens formed by other cases, the optical element 622 can be formed with a different process. A third optical layer 624 can be formed over the second surface of the first portion 620. The third optical layer 624 can be any suitable optical layer. In some cases, the third optical layer 624 can include an antireflective coating. In certain embodiments, the third optical layer 624 can be at least partially reflective, although this is not required.

The multiportion resonant cavity extension 604 further includes a second portion 626 coupled and contoured to the second surface of the first portion 620. Specifically the second portion 626 can be disposed over the third optical layer 624 and/or bonded to the third optical layer 624. Specifically, the second portion 626 can include a first surface and a second surface, separated by a body. The first surface of the second portion 626 can be coupled to the third optical layer 624, and may be a nonplanar surface, as the first surface is configured to engage with and contour to a profile of the optical element 622 and other planar or non-lensing portions of the first portion 620.

As with other embodiments described herein, the second portion 626 includes a second surface opposite the first surface. The second surface in many embodiments can be finished, polished and/or disposed to be a planar surface. In this manner, a thickness of the second portion 626 over the optical element 622 may be less than a thickness of the second portion 626 over other portions of the third optical layer 624. In many examples, the second portion 626 is formed from a dielectric and/or passivating material such as silicon dioxide but this may not be required of all embodiments. In some cases, silicon nitride, crystalline silicon or other materials may be suitable.

As with other embodiments, a fourth reflector 628 can be disposed over the second surface of the second portion 626. The fourth reflector 628 can be a partially reflectivity coating defining an end extent of the multiportion resonant cavity extension 604. To support and/or encapsulate the fourth reflector 628, an optional output coupling substrate can be disposed over the fourth reflector 628, and may define a beam output surface 630.

As a result of the depicted construction, light stimulated from the active layer 606 can reflect from the first reflector 608, through the active layer 606 to become incident upon the second reflector 610. A portion of this light can pass through the photodetector absorption layer 612, and become incident upon the third reflector 614. Some of this light will reflect back toward the active layer 606, and some will enter the multiportion resonant cavity extension 604 through by the second reflector 610. As may be appreciated, the parabolic shape serves to focus light within the multiportion resonant cavity extension 604 toward a central/medial axis of the laser 602.

As described in respect of other embodiments described herein, at least a portion of light incident upon the optical element 622 may be transmitted through the optical element 622 to traverse the second portion 626 of the multiportion resonant cavity extension 604. Thereafter, this light may be reflected by the highly reflective layer, the fourth reflector 628, to traverse through the multiportion resonant cavity extension 604 in the opposite direction.

In this manner, photons stimulated from the active layer 606 resonate between the first reflector 608 and the fourth reflector 628, being concentrated and/or refracted by the optical element 622. As light passes through the optical element 622, it can exit the laser assembly 600 via the surface of the fourth reflector 628. It may be appreciated that as a result of the flat surface of the reflector 624, a beam waist of the output beam may be reduced, thereby exhibiting higher beam divergence.

As used herein, the phrase “at least one of” preceding a series of items, with the term “and” or “or” to separate any of the items, modifies the list as a whole, rather than each member of the list. The phrase “at least one of” does not require selection of at least one of each item listed; rather, the phrase allows a meaning that includes at a minimum one of any of the items, and/or at a minimum one of any combination of the items, and/or at a minimum one of each of the items. By way of example, the phrases “at least one of A, B, and C” or “at least one of A, B, or C” each refer to only A, only B, or only C; any combination of A, B, and C; and/or one or more of each of A, B, and C. Similarly, it may be appreciated that an order of elements presented for a conjunctive or disjunctive list provided herein should not be construed as limiting the disclosure to only that order provided.

One may appreciate that although many embodiments are disclosed above, that the operations and steps presented with respect to methods and techniques described herein are meant as exemplary and accordingly are not exhaustive. One may further appreciate that alternate step order or fewer or additional operations may be required or desired for particular embodiments.

Although the disclosure above is described in terms of various exemplary embodiments and implementations, it should be understood that the various features, aspects and functionality described in one or more of the individual embodiments are not limited in their applicability to the particular embodiment with which they are described, but instead can be applied, alone or in various combinations, to one or more of the some embodiments of the invention, whether or not such embodiments are described and whether or not such features are presented as being a part of a described embodiment. Thus, the breadth and scope of the present invention should not be limited by any of the above-described exemplary embodiments but is instead defined by the claims herein presented.

What is claimed is:

1. A laser assembly comprising:
a vertical cavity surface emitting laser (VCSEL); and
a resonant cavity extension comprising:
a first portion formed from gallium arsenide (GaAs) and defining a microlens aligned with the VCSEL; and
a second portion formed from silicon dioxide (SiO₂) defining:
a first surface contouring to the first portion; and
a planar output surface opposite the first surface; and
a first reflector disposed on the planar output surface such that a resonant cavity is defined between the first reflector and a second reflector within the VCSEL.

2. The laser assembly of claim 1, wherein the microlens is integrally formed with the first portion of the resonant cavity extension.

3. The laser assembly of claim 2, wherein the first portion of the resonant cavity extension is integrally formed with at least one substrate of the VCSEL.

4. The laser assembly of claim 2, wherein the VCSEL is configured for back-side emission.

5. The laser assembly of claim 1, wherein:
the first reflector is a partially reflective distributed Bragg reflector; and
the first portion comprises an antireflective coating.

6. The laser assembly of claim 1, wherein the VCSEL comprises a capped back surface formed from gold.

7. A laser assembly comprising:
a vertical cavity surface emitting laser (VCSEL); and
a resonant cavity extension comprising:
a first portion formed from an optically transparent material and defining a microlens aligned with the VCSEL; and
a second portion comprising:
a spacer engaging the first portion and spaced apart from the microlens;
a planar substrate separated from the first portion by an air gap defined at least in part by the spacer; and
a first reflector disposed on the planar substrate such that a resonant cavity is defined between the first reflector and a second reflector within the VCSEL.

8. The laser assembly of claim 7, wherein the spacer is formed from a thermally conductive metal.

9. The laser assembly of claim 7, wherein:
the first portion is formed from gallium arsenide; and
the planar substrate is formed from silicon dioxide.

10. The laser assembly of claim 7, wherein the planar substrate defines a beam output surface of the laser assembly.

11. The laser assembly of claim 7, comprising a set of etalons disposed over the planar substrate and configured to operate as a mode filter.

12. The laser assembly of claim 7, further comprising a third reflector disposed over the microlens.

13. A laser assembly comprising:
a first reflector;
an active layer coupled to the first reflector;
a second reflector coupled to the active layer;
a cavity extension comprising:
a first portion defining:
a first surface disposed below the second reflector;
a second surface opposite the first surface;
a lens extending from the second surface; and
a third reflector disposed over the second surface and the lens;
a second portion defining:
a third surface coupled to the third reflector and configured to contour to a profile of the second surface and the lens;
a fourth surface defining a plane; and
a fourth reflector disposed on the fourth surface such that a resonant cavity is defined between the first reflector and the fourth reflector, the active layer being disposed within the cavity.

14. The laser assembly of claim 13, further comprising a set of etalons disposed on the fourth reflector and configured to operate as a mode filter.

15. The laser assembly of claim 13, comprising an antireflective coating disposed on the second surface.

16. The laser assembly of claim 13, wherein the first portion is formed from gallium arsenide and the second portion is formed from silicon dioxide.

17. The laser assembly of claim 13, wherein:
the first reflector is a partially reflective distributed Bragg reflector; and
the fourth reflector is a highly reflective distributed Bragg reflector.

18. The laser assembly of claim 13, further comprising:
a substrate; and
wherein the second reflector is formed on the substrate.

19. The laser assembly of claim 18, wherein the first portion is integrally formed with the substrate.

20. The laser assembly of claim 18, wherein the first portion is bonded to the substrate.
